(19) United States
(12) Patent Application Publication
(10) Pub. No.: US 2013/0234747 A1
(43) Pub. Date: Sep. 12, 2013

(54) FINE PITCH PROBE ARRAY FROM BULK MATERIAL

(71) Applicant: ADVANTEST CORPORATION, Tokyo (JP)

(72) Inventor: Lakshmikanth Namburi, Arcadia, CA (US)

(73) Assignee: ADVANTEST CORPORATION, Tokyo (JP)

(21) Appl. No.: 13/788,241

(22) Filed: Mar. 7, 2013

Related U.S. Application Data
(60) Provisional application No. 61/607,893, filed on Mar. 7, 2012.

(51) Int. Cl. G01R 3/00; G01R 1/073

(52) U.S. Cl. CPC G01R 3/00; G01R 1/07307
USPC 324/755.1; 29/832

(57) ABSTRACT

Fine pitch probe array from bulk material. In accordance with a first method embodiment, an article of manufacture includes an array of probes. Each probe includes a probe tip, suitable for contacting an integrated circuit test point. Each probe tip is mounted on a probe finger structure. All of the probe finger structures of the array have the same material grain structure. The probe fingers may have a non-linear profile and/or be configured to act as a spring.

### RELATED APPLICATION

This application claims priority to U.S. Provisional Patent Application 61/607,893, entitled, “A Method to Fabricate Fine Pitch Probe Arrays Using Silicon,” filed 7 Mar. 2012, to Namburi, which is hereby incorporated herein by reference in its entirety.

### FIELD OF INVENTION

Embodiments of the present invention relate to the field of integrated circuit design, manufacture and test. More specifically, embodiments of the present invention relate to systems and methods for fine pitch probe arrays from bulk material.

### BACKGROUND

Integrated circuit testing generally utilizes fine probes to make contact with test points of an integrated circuit in order to inject electrical signals and/or measure electrical parameters of the integrated circuit. Conventional circuit probes are produced singly, and manually assembled into an array corresponding to some or all of the test points on an integrated circuit.

Unfortunately, due to the constraints of producing the probes individually, and assembling them into an array, conventional integrated circuit probe arrays are generally unable to achieve a pitch, e.g., probe to probe spacing, of less than about 50 μm. In addition, conventional probes often have an undesirable high inductance, which may limit the frequency of test signals. Further, conventional integrated circuit probe arrays are typically unable to achieve necessary alignment accuracies in all three dimensions. Still further, such alignment and co-planarity deficiencies of conventional probes deleteriously limit the number of probes and the total area of a probe array, and hence the total area of an integrated circuit that may be tested at a single time. For example, a single conventional integrated circuit probe array assembled at a fine pitch may not be capable of contacting all test points on a large integrated circuit, e.g., an advanced microprocessor.

### SUMMARY OF THE INVENTION

Therefore, what is needed are systems and methods for fine pitch probe arrays from bulk material. What is additionally needed are systems and methods for fine pitch probe arrays from bulk material with fine pitches and high positional accuracy. A further need exists for systems and methods for fine pitch probe arrays from bulk material that are compatible and complementary with existing systems and methods of integrated circuit design, manufacturing and test. Embodiments of the present invention provide these advantages.

In contrast to the conventional art in which an array of electronic probes is constructed by adding individual probes to form an assembly, embodiments in accordance with the present invention form an array of electronic probes from a bulk material, removing material to render the basis of an array of electronic probes.

In accordance with a first method embodiment, an article of manufacture includes an array of probes. Each probe includes a probe tip, suitable for contacting an integrated circuit test point. Each probe tip is mounted on a probe finger structure. All of the probe finger structures of the array have the same material grain structure. The probe fingers may have a non-linear profile and/or be configured to act as a spring.

In accordance with a method embodiment, a bulk material with first and second substantially parallel faces is accessed. A probe base is formed on the first face. A probe tip suitable for contacting an integrated circuit test point is formed on the probe base. The second face is mounted to a carrier wafer. Portions of the bulk material are removed to form a probe finger structure coupled to the probe base and the probe tip. The probe finger structure is coated with a conductive metal electrically coupled to the probe tip. Formation of the probe tip and probe base may include photolithography.

In accordance with another embodiment of the present invention, an electronic probe array for testing integrated circuits includes a plurality of individual probes, mechanically coupled and electrically isolated. Each individual probe includes a probe tip functionally coupled to a probe finger structure. The probe tip is of a different material from the probe finger structure. The probe tip is configured for contacting an integrated circuit test point. Each probe finger structure is formed from a same piece of bulk material. Each individual probe is coated with conductive metal.

### BRIEF DESCRIPTION OF THE DRAWINGS

The accompanying drawings, which are incorporated in and form a part of this specification, illustrate embodiments of the invention and, together with the description, serve to explain the principles of the invention. Unless otherwise noted, the drawings are not drawn to scale.

FIG. 1 illustrates a portion of an exemplary “through-silicon via” (TSV) carrier wafer, in accordance with embodiments of the present invention.

FIG. 2A illustrates formation of a probe block, in accordance with embodiments of the present invention.

FIG. 2B illustrates a formation of slots between rows of probes along one axis to form a probe block, in accordance with embodiments of the present invention.

FIG. 2C illustrates a plan view of a portion of a substrate after the formation of slots, in accordance with embodiments of the present invention.

FIG. 3 illustrates a die bonding of a probe block to a carrier wafer, in accordance with embodiments of the present invention.

FIG. 4 illustrates a sectional view of an array of individual probes, in accordance with embodiments of the present invention.

FIG. 5 illustrates application of a conductive metal coating to an array, in accordance with embodiments of the present invention.

FIG. 6 illustrates removal of the masking layer, exposing the probe tip, in accordance with embodiments of the present invention.

FIG. 7 illustrates a typical application of an array of probes, in accordance with embodiments of the present invention.

### DETAILED DESCRIPTION

Reference will now be made in detail to various embodiments of the present invention, examples of which are illustrated in the accompanying drawings. While the invention will be described in conjunction with these embodiments, it is understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, it will be recognized by one of ordinary skill in the art that the invention may be practiced without these specific details. In other instances, well known methods, procedures, components, and circuits have not been described in detail as not to unnecessarily obscure aspects of the invention.

### Notation and Nomenclature

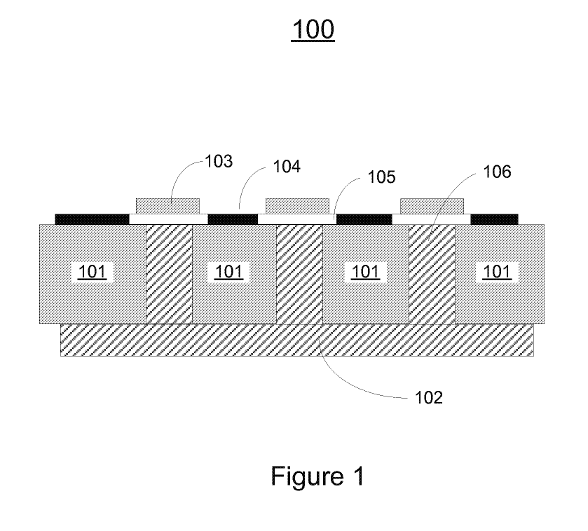

Some portions of the detailed descriptions which follow (e.g., FIGS. 1-7) are presented in terms of procedures, steps, logic blocks, processing, and other symbolic representations of operations on data bits that may be performed on computer memory. These descriptions and representations are the means used by those skilled in the data processing arts to most effectively convey the substance of their work to others skilled in the art. A procedure, computer executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “accessing” or “forming” or “mounting” or “removing” or “coating” or “attaching” or “processing” or “singulating” or “roughening” or “filling” or “performing” or “generating” or “adjusting” or “creating” or “executing” or “continuing” or “indexing” or “computing” or “translating” or “calculating” or “determining” or “measuring” or “gathering” or “running” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

### Fine Pitch Probe Array from Bulk Material

FIG. 1 illustrates a portion of an exemplary “through-silicon via” (TSV) carrier wafer 100, in accordance with embodiments of the present invention. Wafer 100 is illustrated as being formed in silicon, although any suitable material may be utilized. Wafer 100 should generally have parallel top and bottom faces. Any suitable plan-view shape may be used. Wafer 100 comprises a silicon substrate 101 with oxide on sidewalls of the silicon via to insulate the metal via from the semiconducting silicon.

Carrier wafer 100 also comprises a sacrificial ground layer, formed of any suitable material. Sacrificial ground layer 102 will be utilized during wire electrical discharge machining (wire-EDM) processing, further described below, and should be suitable for such purpose. Carrier wafer 100 further comprises a plurality of solder pads 103. Solder pads 103 may comprise an alloy of gold (Au) and tin (Sn), at an exemplary thickness of 2 μm. Under laying solder pads 103 are a plurality of under-bump-metallurgy (UBM) thin film stacks 105. UBM thin film stacks 105 may comprise a film of, for example, titanium (Ti), platinum (Pt) and gold (Au). It is appreciated that other suitable materials may also be used. An insulating layer 104, e.g., silicon dioxide (SiO₂), or other suitable material, separates the stacks of solder pads 103 and UBM 105.

Carrier wafer 100 further comprises a plurality of through-silicon vias (TSV) 106. Through silicon vias 106 provide electrical coupling from the solder pads 103 to the other side of the carrier wafer 100, and to sacrificial ground layer 102.

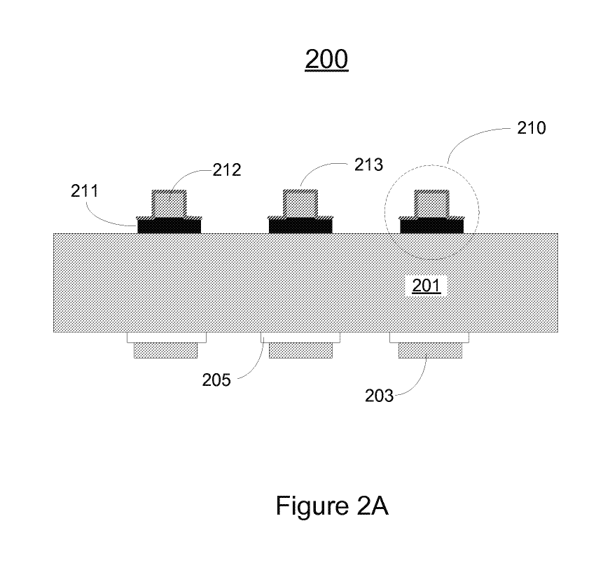

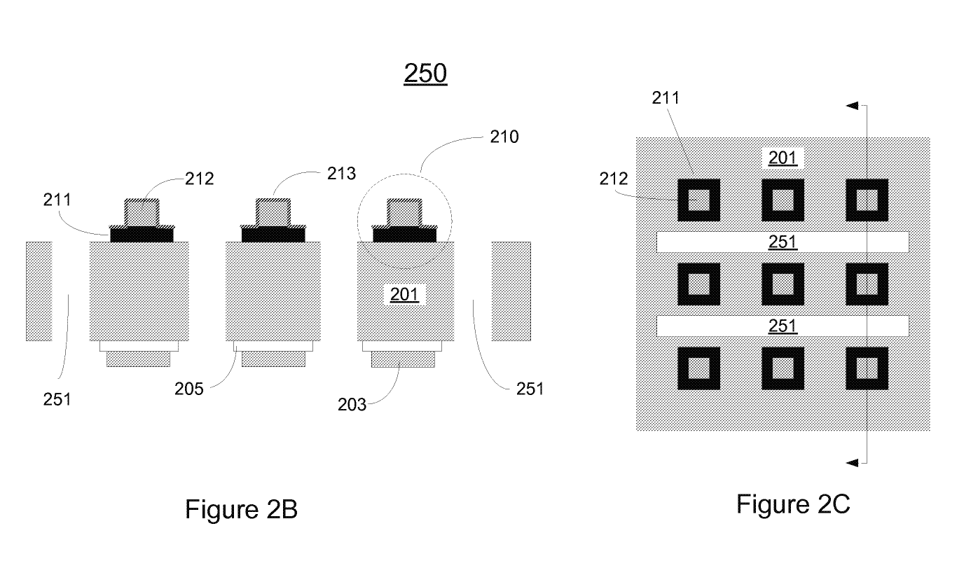

FIG. 2A illustrates formation of a probe block 200, in accordance with embodiments of the present invention. Probe block 200 comprises a substrate 201 comprising silicon, although any suitable material may be utilized, for example, beryllium copper. Silicon substrate 201 may be similar to silicon substrate 101, illustrated in FIG. 1. Silicon substrate 201 may comprise highly doped p-type silicon, doped with boron (B) to a concentration of about 10¹⁸ dopants/cm³, for example, which may produce an electrical resistivity of 0.001 ohm-cm. The thickness of the substrate 201 determines the overall height of the probe array.

Probe block 200 additionally comprises a plurality of solder pads 203. Solder pads 203 may be similar to solder pads 103, illustrated in FIG. 1. Solder pads 203 may comprise an alloy of gold (Au) and tin (Sn), at an exemplary thickness of 2 μm. Under laying solder pads 203 are a plurality of under-bump-metallurgy (UBM) thin film stacks 205. UBM films 205 may be similar to UBM films 105, illustrated in FIG. 1. UBM films 205 may comprise a film of, for example, titanium (Ti), platinum (Pt) and gold (Au). It is appreciated that other suitable materials may be used.

Probe block 200 further comprises a plurality of probes 210. Probes 210 comprise a probe base 211 and a probe tip 212. Probe tip 212 may comprise any material suitable for the probing application, e.g., suitable to contact an integrated circuit test point, for example, a noble metal, e.g., ruthenium (Ru), rhodium (Rh), palladium (Pd), silver (Ag), osmium (Os), iridium (Ir) and/or, platinum (Pt). (It is appreciated that gold (Au) is often included in the noble metals, but is generally considered too soft for probing.) The probe tip 212 and the upper face of the probe base 211 are masked with a masking layer 213, e.g., a non-conductive polymer. The probe base 211 may be fabricated by sputtering a seed layer on one side of the wafer, and lithographically patterned and plated. Probe tips 212 may be fabricated on top of the probe base by lithographically patterning photoresist, plating the tip material and etching the seed layer between the tip bases. The probe tips 212 may be planarized if necessary for a smooth finish. The probe tips 212 should then coated to protect them from the rest of the process.

FIG. 2B illustrates a formation of slots 251 between rows of probes 210 along one axis to form probe block 250, in accordance with embodiments of the present invention. It is appreciated that slots 251 represent the absence of substrate material. In some embodiments, slots 251 may remove an entire thickness of substrate 201. It is appreciated that substrate 201 is not completely singulated; portions of substrate 201 remain coupled outside of the plane of FIG. 2B. Slots 251 may be formed by any suitable process, including, for example, deep reactive ion etching (DRIE).

FIG. 2C illustrates a plan view of a portion of substrate 201 after the formation of slots 251, in accordance with embodiments of the present invention. Slots 251 are substantially parallel, and separate “rows” of probes 210 from one another. Mask 213 is not illustrated in FIG. 2C for clarity.

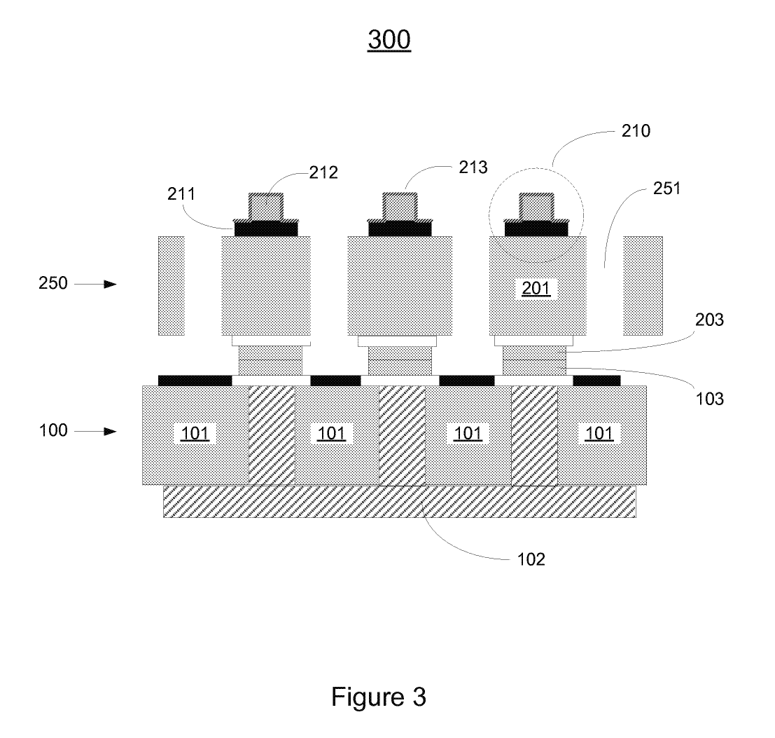

FIG. 3 illustrates a die bonding 300 of probe block 250 to carrier wafer 100, in accordance with embodiments of the present invention. Bond pads 103 (FIG. 1) are bonded to bond pads 203 (FIGS. 2A, 2B) by any suitable process.

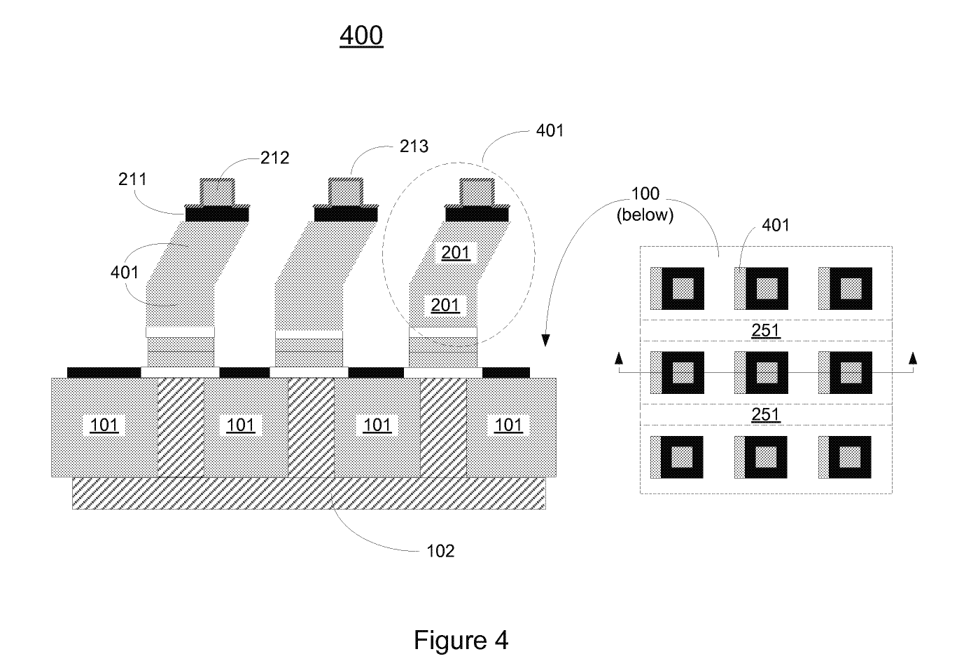

FIG. 4 illustrates a sectional view of an array 400 of individual probes 401, in accordance with embodiments of the present invention. It is to be appreciated that the plane of FIG. 4 is perpendicular to the plane of FIG. 3. For example, the plane of FIG. 4 is parallel to, but not coincident with, the slots 251, as illustrated in FIG. 2C. Individual proves 401 comprise a probe tip 212, a probe base 211 and a probe finger structure 402. It is appreciated that all probe fingers 402 will have the same material grain structure, as they are formed from the same block of material, e.g., single crystal silicon.

It is to be appreciated that individual probes 401 may have a complex shape in at least one dimension, in accordance with embodiments of the present invention. For example, as illustrated in FIG. 4, probe fingers 401 are not linear, e.g., they are “bent” to the right. Such a profile, in one or more dimensions, may allow each individual probe to function as a spring, allowing for compliance to slight irregularities in a surface of an integrated circuit, and providing a restorative force to keep the probe tip, e.g., 212, in contact with an integrated circuit test point.

In accordance with embodiments of the present invention, such “non-straight” or non-linear probe profiles may be accomplished by wire electrical discharge machining (wire-EDM). For example, a wire of about 12 μm in diameter may be used to machine probes at fine pitch geometries less than 40 μm. It is appreciated that a probe pitch may be different in X and Y dimensions, and it is not necessarily the same, even in the same dimension. Although the probe fingers 401 are illustrated as being “straight” in the plane of FIG. 2B, wire electrical discharge machining could be applied to that stage as well, e.g., replacing deep reactive ion etching, to produce a more complex shape in that dimension, as well, in accordance with embodiments of the present invention. It is further appreciated that embodiments in accordance with the present invention may form probes with a pitch greater than about 40 μm. For example, a wire of greater than about 12 μm in diameter may be used to machine probes at larger pitches. Probes formed in accordance with embodiments of the present invention at such larger pitches continue to enjoy significant advantages over the conventional art, including, for example, lower cost, less complexity and exceptional precision in probe tip positional accuracy in all three dimensions.

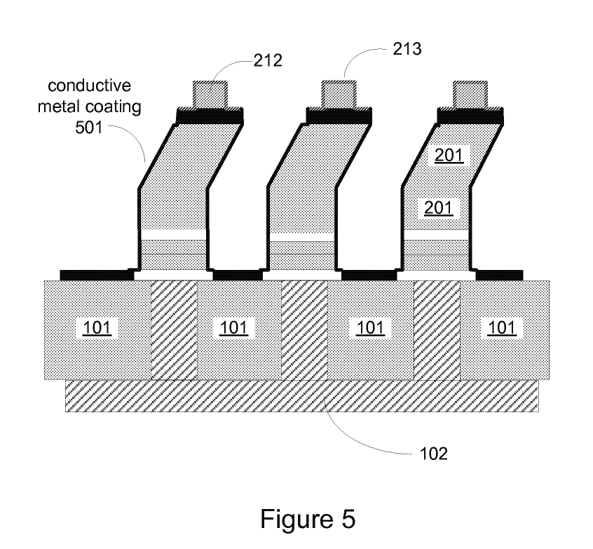

FIG. 5 illustrates application of a conductive metal coating 501 to array 400, in accordance with embodiments of the present invention. The conductive metal coating 501 may comprise gold (Au) and/or copper (Cu), or other suitable materials, and may be applied by any suitable process, including, for example, immersion plating or electro-less plating processes. The thickness of the conductive metal coating 501 may be determined by the required current carrying capability of the probes. Conductive metal coating 501 may not be required in the case that material 201 is a metal such as berellium-copper (BeCu) since it is sufficiently conductive, unlike doped silicon.

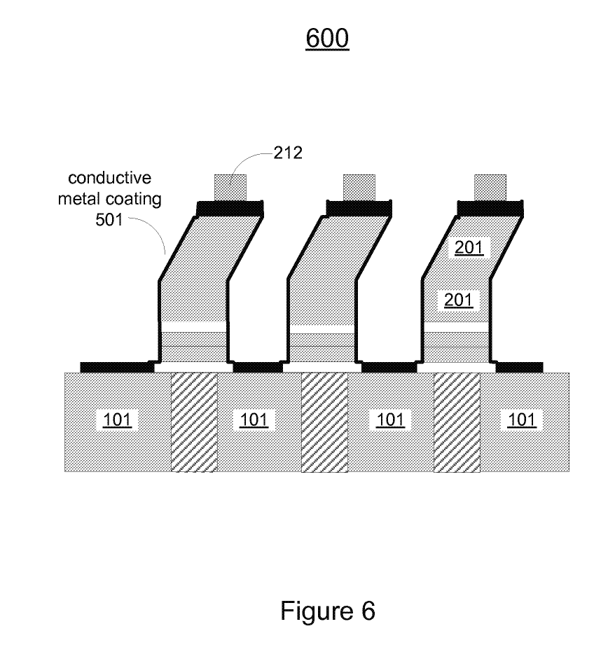

In FIG. 6, the masking layer 213 (FIG. 2) is removed, exposing the probe tip 212, via any suitable process, for example, using a dry reactive ion etch process or by using suitable wet chemistry. In addition, the sacrificial ground layer 102 (FIG. 1) is removed. In this manner, an array of electrical probes 600 is formed from a bulk material, in accordance with embodiments of the present invention.

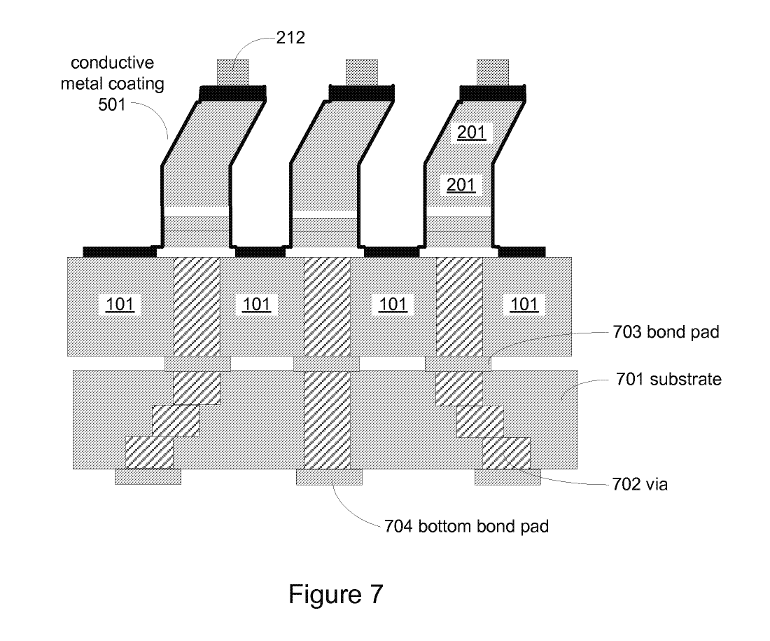

FIG. 7 illustrates a typical application of array of probes 600 (FIG. 6), in accordance with embodiments of the present invention. As illustrated in FIG. 7, the array of electrical probes 600 is bonded to a space transforming substrate 701. Space transforming substrate 701 serves to transform the spacing of the probe heads 712, which may be on a pitch suitable for probing integrated circuits, e.g., less than or equal to about 40 μm, to a pitch more suitable for printed circuit boards, e.g., about 1 mm.

Substrate 701 may be similar to substrate 101 (FIG. 1), although that is not required. Space transforming substrate 701 is electrically and mechanically bonded to array of probes 600 via any suitable processes and materials, for example via solder bonding pads 703. Bottom bond pads 704 serve to couple space transforming substrate 701 to a higher level assembly, for example, a printed circuit board.

In accordance with embodiments of the present invention, the individual probes of the array 600 are formed from a bulk material, e.g., from single crystal silicon with a high modulus. Such material functions as a spring without any appreciable plastic deformation. The complex shape increases the spring characteristic of the probes, allowing for compliance to slight irregularities in a surface of an integrated circuit, and providing a restorative force to keep the probe tip, e.g., 212, in contact with an integrated circuit test point. The probe tips exhibit a fine pitch, e.g., less than 40 μm, with excellent planarity and tip positional accuracy, as the probe tips are lithographically defined. The probe array has a high current carrying capability due to the conductive metal coating. Further, probe arrays in accordance with the present invention may be produced with shorter lead times and at reduced cost in comparison with the conventional art, as there is no manually assembly, and the processes leverage the economics of integrated circuit manufacturing.

Embodiments in accordance with the present invention provide systems and methods for fine pitch probe arrays from bulk material. In addition, embodiments in accordance with the present invention provide systems and methods for fine pitch probe arrays from bulk material with fine pitches and high positional accuracy. Further, embodiments in accordance with the present invention provide systems and methods for fine pitch probe arrays from bulk material that are compatible and complementary with existing systems and methods of integrated circuit design, manufacturing and test.

Various embodiments of the invention are thus described. While the present invention has been described in particular embodiments, it should be appreciated that the invention should not be construed as limited by such embodiments, but rather construed according to the below claims.

What is claimed is:

1. An article of manufacture comprising:
an array of probes, wherein each probe comprises:
a probe tip, suitable for contacting an integrated circuit test point;
said probe tip mounted on a probe finger structure,
wherein all said probe finger structures of said array have the same material grain structure.

2. The article of manufacture of claim 1 wherein said probe finger structure has a non-linear profile.

3. The article of manufacture of claim 2 wherein said probe finger structure is configured to act as a spring.

4. The article of manufacture of claim 1 further comprising a conductive metal coating on said probe finger structure, wherein said coating is in electrical contact with said probe tip,

5. The article of manufacture of claim 1 wherein said probe tip comprises a noble metal excluding gold.

6. The article of manufacture of claim 1 wherein said probe tips of said array of probes are arranged on a grid of less than 50 μm.

7. The article of manufacture of claim 1 wherein said array of probes is functionally coupled to a space transforming substrate, for transforming a pitch of said array of probes to a larger pitch.

8. A method comprising:
accessing a bulk material with first and second substantially parallel faces;
forming a probe base on said first face;
forming a probe tip suitable for contacting an integrated circuit test point on said probe base;
mounting said second face to a carrier wafer;
removing portions of said bulk material to form a probe finger structure coupled to said probe base and said probe tip; and
coating said probe finger structure with a conductive metal electrically coupled to said probe tip.

9. The method of claim 8 wherein said forming a probe base and said forming a probe tip comprise photolithography.

10. The method of claim 8 wherein said probe tip comprises rhodium (Rh).

11. The method of claim 8 wherein said removing comprises deep reactive ion etching (DRIE).

12. The method of claim 8 wherein said removing comprises wire electrical discharge machining (wire-EDM).

13. The method of claim 8 further comprising masking said probe tip prior to said coating.

14. The method of claim 8 wherein said removing forms a non-linear probe finger structure.

15. An electronic probe array for testing integrated circuits comprising:
a plurality of individual probes, mechanically coupled and electrically isolated,
wherein each said individual probe comprises a probe tip functionally coupled to a probe finger structure,
wherein said probe tip is of a different material from said probe finger structure,
wherein said probe tip is configured for contacting an integrated circuit test point,
wherein each probe finger structure is formed from a same piece of bulk material, and
wherein each said individual probe is coated with conductive metal.

16. The electronic probe array of claim 15 wherein said probe finger structure has a non-linear profile.

17. The electronic probe array of claim 15 wherein said probe finger structure is configured to act as a spring.

18. The electronic probe array of claim 15 further comprising a space transforming substrate, for transforming a pitch of said plurality of individual probes to a larger pitch.

19. The electronic probe array of claim 15 wherein said probe tip comprises a noble metal

20. The electronic probe array of claim 15 wherein two of said plurality of individual probes are closer than 50 μm from one another.
